(19) United States
(12) Patent Application Publication
(10) Pub. No.: US 2024/0282869 A1
(43) Pub. Date: Aug. 22, 2024

(54) DEVICE AND METHOD FOR IMPROVING THE OHMIC CONTACT BETWEEN A FRONT CONTACT GRID AND A DOPED LAYER OF A WAFER SOLAR CELL

(71) Applicants: HANWHA Q CELLS GMBH, Bitterfeld-Wolfen (DE); CE Cell Engineering GmbH, Kabelsketal (DE)

(72) Inventors: Florian STENZEL, Bitterfeld-Wolfen (DE); Ansgar METTE, Bitterfeld-Wolfen (DE); Stefan HOERNLEIN, Bitterfeld-Wolfen (DE); Martin SCHAPER, Bitterfeld-Wolfen (DE); Axel SCHWABEDISSEN, Bitterfeld-Wolfen (DE); Janko CIESLAK, Bitterfeld-Wolfen (DE); Eckehard HOFMUELLER, Kabelsketal (DE); Stefan STOECKEL, Kabelsketal (DE); Eve KRASSOWSKI, Kabelsketal (DE)

(21) Appl. No.: 18/581,071

(22) Filed: Feb. 19, 2024

(30) Foreign Application Priority Data
Feb. 20, 2023 (DE) 102023104173.8

(51) Int. Cl. H01L 31/0224; H01L 31/18

(52) U.S. Cl. CPC H01L 31/022441; H01L 31/188

(57) ABSTRACT

A device for improving ohmic contact between a front contact and a doped layer of a wafer solar cell having a front, a back, the front contact, the doped layer and a back contact. The front and back contacts are strip-shaped or grid-shaped. The device having: two contacting apparatuses for electrically contacting the front and back contacts; a voltage source having a pole for electrical connection to one contacting apparatus and a pole for connection to the other contacting apparatus; and two point light sources to illuminate the front and the back. The contacting apparatuses each have: an optically-transparent material coated with an optically-transparent, electrically-conductive layer; an optically-transparent material having microscopically-thin, electrically-conductive wires integrated into a surface of the optically-transparent material; an optically-transparent, electrically-conductive material having microscopically-thin, electrically-conductive wires integrated into a surface of the optically-transparent, electrically-conductive material; or, a braid or a network of microscopically-thin, electrically-conductive wires.

### PRIORITY CLAIM

The present application claims priority to German Patent Application No. 102023104173.8, filed on Feb. 20, 2023, which said application is incorporated by reference in its entirety herein.

### FIELD OF THE INVENTION

The invention relates to a method for improving the ohmic contact between a front contact grid and a doped layer of a wafer solar cell. A front of the wafer solar cell represents a Sun-facing side of the wafer solar cell during operation of the wafer solar cell, while a back of the wafer solar cell represents a side of the wafer solar cell that faces away from the Sun.

### BACKGROUND OF THE INVENTION

Depending on the process control during the production of the wafer solar cell with the emitter layer in the form of a doped layer and the front contact grid, there may be high contact resistances in places at the junction between a metal paste provided for producing the front contact grid and the doped layer. Such excessively high contact resistances as a rule lead to a reduced efficiency for the wafer solar cell.

DE 10 2016 009 560 A1 and DE 10 2018 001057 A1 disclose methods for improving the ohmic contact between the front contact grid and the doped layer in the form of an emitter layer. In this case, first of all, a silicon wafer solar cell having the doped layer, the front contact grid and a back contact is provided. Then the front contact grid is electrically connected to a pole of a voltage source and a contacting apparatus electrically connected to the other pole of the voltage source is connected to the back contact. The voltage source is used to apply a voltage directed counter to the forward direction of the silicon wafer solar cell, which voltage is smaller in magnitude than the breakdown voltage of the silicon wafer solar cell. When the voltage is applied, a point light source is guided over the Sun-facing front of the silicon wafer solar cell. A section of a partial region of the Sun-facing side is illuminated in the process, and a current flow is thus locally induced in the partial section. This current flow related to the section has a current density from 200 A/cm² to 20,000 A/cm² and acts on the partial section for 10 ns to 10 ms.

The method is used to locally and subsequently improve the contact resistance of the wafer solar cell by applying the reverse voltage and local illumination. In the process, a high current flows through a very small area and improves the metal-to-semiconductor contact there. To apply the voltage, the wafer solar cell has to be contacted on both sides. At the same time, the contacting apparatuses also regularly lie in the light path of the point light source, such that no or only incomplete processing takes place in the region of contacting apparatuses, for example in the form of opaque strips.

FIG. 1 shows a cross-sectional view of a device known from the prior art according to DE 10 2016 009 560 A1. The wafer solar cell 1 has a front 11 and a back 12. A front contact 14 is arranged on the front 11 and a back contact 15 is arranged on the back 12. The front contact 14 and/or the back contact 15 are strip-shaped or grid-shaped. The device furthermore has:
a contacting apparatus 3 for making electrical contact with the front contact 14, wherein the contacting apparatus 3 is designed as four wires arranged in parallel, one of which may be seen in section in FIG. 1,
a further contacting apparatus 2 for making electrical contact with the back contact 15, wherein the further contacting apparatus 2 has an electrically conductive material that covers the full surface of the back 12 when electrical contact is made and is optically non-transparent,
a voltage source 7 having a pole for electrical connection to the contacting apparatus 3 and a further pole for electrical connection to the further contacting apparatus 2 and
a point light source 4 configured and designed to illuminate the front 11 of the wafer solar cell 1.

In the associated method known from the prior art, the front contact 14 is electrically contact-connected to the contacting apparatus 3, and the back contact 15 is electrically contact-connected to the further contacting apparatus 2. Furthermore, a voltage is applied by way of the voltage source 7 in order to generate a reverse current, and the point light source 4 is guided over the front 11 such that a light beam 5 locally illuminates a partial section of the front 11.

In this method, however, significant voltage losses occur in the path of the induced current over the front contact 14. In addition, the contacting apparatus 3 in the form of the four wires shades the point light source 4 and entails the risk of damage for the wafer solar cell 1 due to the mechanical interaction. Furthermore, the wires may burn through due to local very high currents that occur in what are known as shunts.

Another device according to the prior art is shown in cross section in a method for improving the ohmic contact between the front contact grid and the doped layer of a wafer solar cell in FIGS. 2a to 2c. FIG. 2a shows a cross-sectional view of the device, which corresponds to the device shown in FIG. 1, with the difference that the contacting apparatus 3 does not have four wires, but rather has two electrically conductive, opposing strips and that the voltage source is not shown for the sake of clarity. As shown in FIG. 2a, one of the two electrically conductive strips contacts the front contact 14, while the other of the two electrically conductive strips does not contact the front contact 14 because the point light source 4 is guided over the partial section of the front contact 14 and is moved over the front of the wafer solar cell 1. Shading of the illuminated partial section is thus avoided. The other strip is then connected opposite the first, while the point light source 4 is guided over a central partial section of the wafer solar cell 1. The one strip is then removed, such that, in FIG. 2c, the point light source 4 is also able to process a partial section of the wafer solar cell 1 that is shaded thereby in FIG. 2a. This type of electrical contact causes significant voltage losses for the induced current over the front contact 14 up to the illuminated operating point. The current at the edge of the wafer solar cell 1 has to flow through the complete front contact 14 to the opposite strip. As a result, the applied voltage at the illuminated operating point is unevenly distributed over the area of the wafer solar cell 1 and thus the process cannot act homogeneously over the front of the wafer solar cell 1. Furthermore, an electrically conductive strip is not redundant. As soon as a strip contacts the front contact 14 incompletely, the processing fails.

The shading of the wafer solar cell by the contacting apparatuses therefore leads to problems. A portion of the voltage drops due to the solar cell contacts on account of resistance. A contact point near the contacting apparatus thus experiences other effective process parameters than a contact point further away from the contacting apparatus. The applied reverse voltage, which has a significant influence on the quality of the process, is thus considered to be inhomogeneous over the front of the wafer solar cell. This leads to a wafer solar cell with reduced efficiency.

### SUMMARY OF THE INVENTION

One object of the invention is to provide a device and a method for improving the ohmic contact between a front contact and a doped layer of a wafer solar cell, by way of both of which shading is prevented or at least reduced and more homogeneous process control is possible in order to increase the efficiency of the wafer solar cell.

According to the invention, the object is achieved by devices and methods having features of the various claims and embodiments described herein. Advantageous developments and modifications are specified in the claims and are explained below.

The reverse current is brought to the light point position generated by the point light source without losses or at least with reduced losses at each solar cell contact point, since the path to this position is short.

The device and the method provide transparent, full-surface conductive pressing onto the sides of the wafer solar cell that are to be illuminated. For example, adhesively bonded, embedded, transparent pressure plates that are provided with electrical conductors and that avoid large-area shading for the point light source, or an open network consisting of electrical conductors that is stretched over one side of the wafer solar cell and that avoids large-area shading, are provided as contacting apparatuses, such that the front and back contact of the wafer solar cell is thereby electrically contacted and is able to be illuminated at the same time. The reverse current thus always has short paths, and each contact of the corresponding contact grid is able to be optimized. In addition, the solar cells may already be electrically contact-connected to the contacting apparatuses before they are illuminated, such that a sandwich consisting of the wafer solar cell and the two contacting apparatuses is able to be illuminated without delay.

The contacting units are preferably optimized for low voltage losses. Since two contacting apparatuses are offset from one other on the front and back of the wafer solar cell, the illumination takes place from both sides, but preferably not at the same point. Partial sections that are shaded on one side of the wafer solar cell are preferably processed by the illumination of the other side.

This means that neither voltage losses nor unprocessed regions occur due to shaded regions. Due to the increased number of contacts, there is more freedom when designing the front and back contacts. It is possible to implement interruptions in the contacts such as contact fingers and power collectors such as busbars. There is also greater redundancy against faults in the front and back contacts. A further advantage of this contacting is that the contacting apparatuses are able to be used simultaneously as a transport unit and, particularly advantageously, are able to be operated in a cyclic process.

The invention relates to a device for improving the ohmic contact between a front contact and a doped layer of a wafer solar cell, the wafer solar cell having:
a front, a back, the front contact, the doped layer and a back contact, wherein the front contact and the back contact are strip-shaped or grid-shaped,
the device having
   two contacting apparatuses, one for making electrical contact with the front contact and the other for making electrical contact with the back contact,
   a voltage source having a pole for electrical connection to one of the contacting apparatuses and a further pole for electrical connection to the other of the contacting apparatuses,
   two point light sources, one point light source configured and designed to illuminate the front of the wafer solar cell and the other point light source configured and designed to illuminate the back of the wafer solar cell,

According to the invention, provision is made for the contacting apparatuses each to have:
an optically transparent material that is coated with an optically transparent, electrically conductive layer, or
an optically transparent material having a multiplicity of microscopically thin, electrically conductive wires that are integrated into a surface of the optically transparent material, or
an optically transparent, electrically conductive material having a multiplicity of microscopically thin, electrically conductive wires that are integrated into a surface of the optically transparent, electrically conductive material, or
a braid or a network consisting of a multiplicity of microscopically thin, electrically conductive wires.

The first variant of the further contacting apparatus is optically transparent over its full surface and at the same time electrically conductive over its full surface, such that negative effects due to shading and voltage losses do not occur or are minimized up to the illuminated operating point. The further contacting apparatus is configured, designed and arranged to make electrical contact with the front contact or the back contact. Within the meaning of the invention, a material is said to be optically transparent when it has a transmission of at least 90% in a spectrum with a wavelength range of 400 to 1,500 nm.

The other variants regarding the design of the contacting apparatus include the use of microscopically thin, electrically conductive wires. The feature of a microscopically thin wire requires a wire diameter of less than one millimetre. Preferably, these wires have diameters of less than 500 micrometres, particularly preferably of less than 200 micrometres. With these wire diameters, the illuminated region of the point light source that is used is significantly larger than the diameter of the conductive wires. By using such thin wires, the correspondingly designed contacting apparatuses appear to be optically transparent when observed macroscopically.

The device and the method provide optically transparent or at least macroscopically optically transparent, full-surface conductive pressing for the electrical contact structures on that side of the wafer solar cell that is to be illuminated. The front contact or back contact of the wafer solar cell is thereby electrically contacted and at the same time the corresponding solar cell surface on which the contacting apparatus is arranged so as to cover the surface is able to be illuminated. The reverse current, which is important for the heat effect, thereby always has short paths, so as to minimize the voltage loss that occurs. Each contact of the corresponding contact grid is thereby able to be optimized under very similar process parameters. In addition, the wafer solar cells may already be electrically contact-connected to the contacting apparatuses before they are illuminated, such that a sandwich consisting of the wafer solar cell and the two contacting apparatuses is able to be illuminated without delay. This also saves time during production.

In one preferred embodiment, the optically transparent material coated with an optically transparent, electrically conductive layer is formed as an optically transparent material in the form of glass or plastic coated with optically transparent conductive oxides. The electrically conductive oxides may be formed as TCO (transparent conductive oxides) such as for example ITO (indium-tin oxide) or ZnO:Al. This makes it possible to achieve full-surface electrical contact with the front contact or back contact, while at the same time ensuring the illumination of that side of the wafer solar cell that is electrically contact-connected to the further contacting apparatus.

The optically transparent material is preferably glass or a transparent plastic. The optically transparent, electrically conductive material is preferably made of TCO, for example ITO or ZnO:Al.

Preferably, the multiplicity of electrically conductive wires are aligned parallel to one another, embedded in the surface of the transparent material in the form of a grid or braid. This also guarantees full-surface electrical contact with the front contact or back contact, ensuring simultaneous transparency that is sufficient for the illumination of the point light sources.

In one preferred embodiment, the multiplicity of microscopically thin, electrically conductive wires is formed from metal and/or from a metal alloy. Preferably, the multiplicity of microscopically thin, electrically conductive wires are formed from semi-precious and/or precious metals, for example in the form of metal threads in the form of silver, gold or copper threads.

Preferably, the front contact and the back contact have contact fingers each arranged parallel to one another, having a contact finger width oriented parallel to the surface of the wafer solar cell and perpendicular to a direction of extent of the contact fingers. The microscopically thin, electrically conductive wires of the multiplicity of wires preferably each have a width smaller than the contact finger width. This also ensures minimized shading.

The point light source may be for example a laser, a light-emitting diode or focused radiation from a flash lamp. The point light source preferably emits radiation having wavelengths in the range from 400 nm to 1500 nm. Preferably, the point light source is a laser, in particular a laser diode.

The invention furthermore relates to a method for improving the ohmic contact between a front contact and a doped layer of a wafer solar cell using the device according to one or more of the embodiments described above, having the following steps:
a) electrically contact-connecting the front contact to one of the contacting apparatuses and the back contact to the other of the contacting apparatuses;
b) applying a voltage directed counter to the forward direction of the wafer solar cell to the front contact and the back contact by way of the voltage source, wherein the applied voltage is smaller in magnitude than the breakdown voltage of the wafer solar cell,
c) guiding one of the point light sources over a front partial section of the Sun-facing front during the application of the voltage and guiding the other of the point light sources over a back partial section of the back facing away from the Sun, wherein the distance between the front partial section and the back partial section is less than 5 mm, preferably less than 3 mm, such that a current flow is induced in these partial sections and acts on these partial sections.

In order to avoid shading, closely located contact units of the front contact or back contact are preferably electrically contact-connected alternately at the front or back to the correspondingly assigned contacting apparatus. As a result, the heating reverse current always has short paths upon application of the voltage and illumination, and each contact point of the front contact is able to be optimized by illumination from the side that is unshaded at this operating point.

In one preferred embodiment, steps a) to c) are performed statically in the device. The method is suitable for static performance and for the processing of individual wafer solar cells.

Preferably, however, the device is designed as a component of an inline production facility for wafer solar cells. Step a) comprises loading the contacting apparatuses with the wafer solar cell, for example from a loading belt, and contact-connecting the wafer solar cell to the contacting apparatuses on both sides. The wafer solar cell is transported, between steps a) and c), using the contacting apparatuses as a transport unit for the wafer solar cell, from a loading/contact zone of the device, in which step a) is performed, to an illumination zone, in which steps b) and c) are performed, and then transported to an unloading zone in which the contacting apparatuses are spatially separated from the wafer solar cell. Here, the wafer solar cell is unloaded onto an unloading belt. A cycle time for the method is reduced.

Preferably, the contacting apparatuses of the device, which is designed as a component of an inline production facility, are moved, together with contacted wafer solar cells, in one inline transport cycle, from the loading/contact zone, through the illumination zone to the unloading zone and back to the loading/contact zone again in a return transport loop. The two contacting apparatuses are thereby guided in a cyclic system or method. After unloading, they are returned outside the process region for reloading. This also makes it possible to significantly reduce the cycle time. Instead of contacting, processing and unloading the wafer solar cell in one cycle, the steps are separated. Each step is performed in one cycle.

The method is preferably performed with the following parameters:

A voltage, which is in the range from 1 to 40 V, is applied by way of the voltage source to the front contact grid and the back contact grid counter to the forward direction. Preferably, the local illumination has a power density in the range from 200 to 500,000 W/cm². The method is preferably carried out such that a current from 0.1 to 10 A flows between the front and back contacts.

Preferably, the provided wafer solar cell has a contact resistance of >50mOhmcm², measured with the TLM method (transfer length method), before the method according to the invention is performed. In one preferred embodiment, the provided wafer solar cell has a contact area of less than 0.1% prior to performing the method according to the invention. This means that the metallized area of the metal semiconductor contacts corresponds to less than 0.1% of the surface on which the metal semiconductor contacts are located. Preferably, the provided wafer solar cell has one or more passivation and/or anti-reflection layers. Preferably, the anti-reflection layer has a thickness of more than 100 nm. The anti-reflection layer is formed, for example, from SiNₓ (silicon nitride). The anti-reflection layer may also be formed as a SiNₓ (silicon nitride)/SiOₓN_{y} (silicon oxynitride) double layer or SiNₓ (silicon nitride)/SiOₓN_{y} (silicon oxynitride)/SiO₂ (silicon dioxide) triple layer with thicknesses greater than 100 or greater than 110 nm. Preferably, the provided wafer solar cell has a higher layer resistance of the doped layer on the front than on the back.

The wafer solar cell subjected to the method may be a single solar cell, a multiple solar cell or a subcell of a multiple solar cell.

Further advantages and properties of the method are explained with reference to the preferred embodiments described below. However, the figures are not illustrated to scale and should therefore be understood to be purely schematic and exemplary.

### BRIEF DESCRIPTION OF THE FIGURES

In the figures, in each case schematically and not to scale:

FIG. 1 shows a cross-sectional view of a device according to the prior art;

FIG. 2a-2c each show a cross-sectional view of another device according to the prior art, which carries out a method according to the prior art;

FIG. 3 shows a cross-sectional view of a device according to a first embodiment, which carries out a step of the method according to the invention;

FIG. 4 shows a cross-sectional view of a device according to a second embodiment, which carries out a step of the method according to the invention;

FIG. 5 shows a cross-sectional view of a device according to a third embodiment, which carries out a step of the method according to the invention; and

FIG. 6 shows a perspective view of a device according to a fourth embodiment, which carries out a method according to the invention.

### DETAILED DESCRIPTION

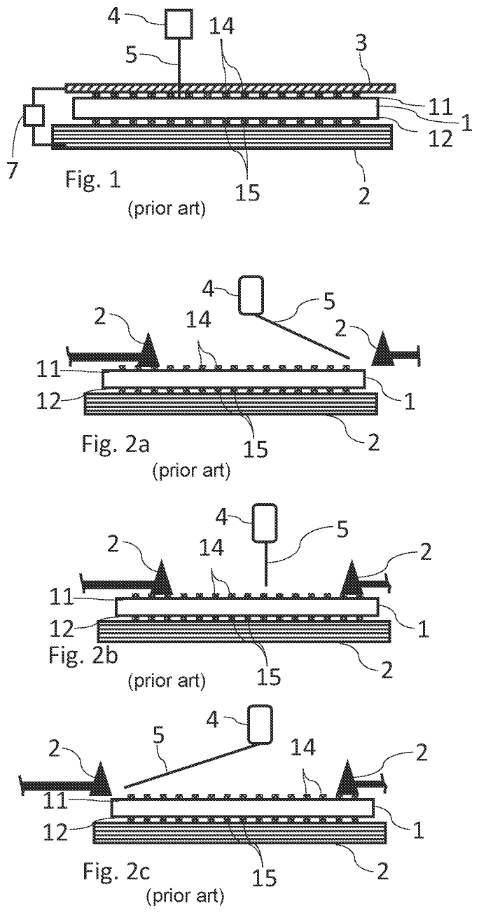

FIG. 1 shows a cross-sectional view of a device according to the prior art, and FIG. 2a-2c each show a cross-sectional view of a further device according to the prior art, which carries out a method known from the prior art. Reference is made to the above explanations with regard to these figures in the introduction to the description.

FIG. 3 shows a cross-sectional view of a device according to a first embodiment, which carries out a step of the method according to the invention. The device shown in FIG. 3 corresponds to the device shown in FIG. 1 with the difference that, instead of the contacting apparatuses 2, 3, it has the contacting apparatuses 6, which have an optically transparent material that is coated with an optically transparent, electrically conductive layer. One point light source 4 illuminates a partial section of the front 11 with a light beam 5 and the other point light source 4 illuminates a further partial section of the back 12 locally with a light beam 5, during the application of a voltage directed counter to the forward direction of the wafer solar cell 1 by way of the voltage source 7, the contacting apparatus 2 and the further contacting apparatus 6 on the front contact 14 and the back contact 15, wherein the applied voltage is smaller in magnitude than the breakdown voltage of the wafer solar cell 1 and wherein a distance between the front partial section and the back partial section is less than 5 mm, such that a current flow is induced in these partial sections and acts on these partial sections.

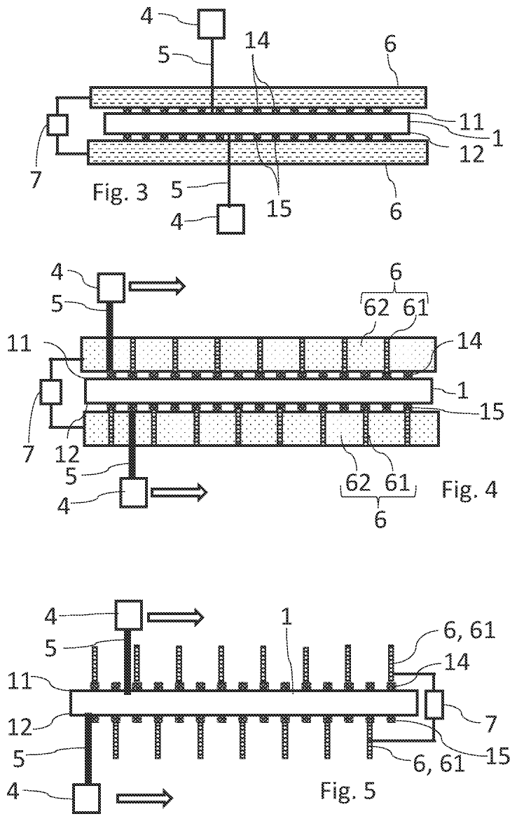

FIG. 4 shows a cross-sectional view of a device according to a second embodiment, which carries out a step of the method according to the invention. The device shown in FIG. 4 corresponds to the device shown in FIG. 3 with the difference that the contacting apparatuses 6 each have an optically transparent material 62 having a multiplicity of microscopically thin, electrically conductive wires 61 that are integrated into a surface of the optically transparent material 62. During the generation of the reverse current, the point light sources 4 are guided over the front 11 and the back 12 in the direction of the arrow.

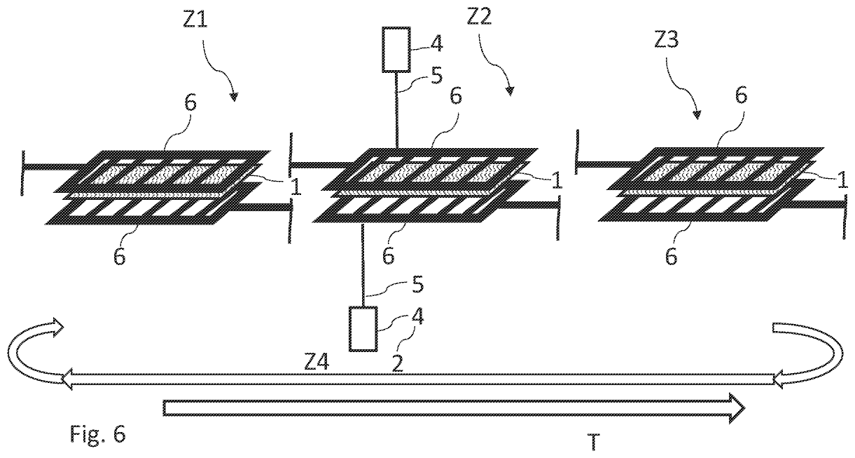

FIG. 5 shows a cross-sectional view of a device according to a third embodiment, which carries out a step of the method according to the invention. The device shown in FIG. 6 corresponds to the device shown in FIG. 4 with the difference that the contacting apparatuses 6 each have a braid or a network consisting of a multiplicity of microscopically thin, electrically conductive wires 61.

FIG. 6 shows a perspective view of a device according to a fourth embodiment, which carries out a method according to the invention. The device is designed as a component of an inline production facility for wafer solar cells 1. It is used to improve the ohmic contact between a front contact (not shown in FIG. 6) and a doped layer (not shown) of a wafer solar cell 1 that has the front contact, the doped layer, a back contact (not shown in FIG. 6), wherein the front contact and the back contact are each strip-shaped or grid-shaped. The device has two contacting apparatuses 6 for making electrical contact with the front contact and the back contact. It also has a voltage source (not shown in FIG. 6) having a pole for electrical connection to one contact apparatus 6 and a further pole for electrical connection to the other contact apparatus 6 and two point light sources 4, one of which is configured and designed to illuminate a partial section of the front of the wafer solar cell 1 with a light beam 5, and the other of which is configured and designed to illuminate a further partial section of the back of the wafer solar cell 1 with a light beam 5. The contacting apparatuses 6 each have an optically transparent material that is coated with an optically transparent, electrically conductive layer or an optically transparent material (not shown) having a multiplicity of microscopically thin, electrically conductive wires (not shown) that are integrated into a surface of the optically transparent material, or a braid or a network consisting of a multiplicity of microscopically thin, electrically conductive wires (not shown). It also has a loading/contact zone Z1, an illumination zone Z2, an unloading zone Z3 and a return transport loop Z4.

In the loading/contact zone Z1, the contacting apparatuses 6 are loaded with the wafer solar cell 1, the front contact is electrically contact-connected to the further contacting apparatus 6 and the back contact is electrically contact-connected to the contacting apparatus 2. The sandwich, consisting of the wafer solar cell 1 with the two contacting apparatuses 6, is then transported from the loading/contact zone Z1 to the illumination zone Z2, using the contacting apparatuses 6 as a transport unit for the wafer solar cell 1. In the illumination zone Z2, a voltage directed counter to the forward direction of the wafer solar cell 1 is applied to the front contact and the back contact by way of the voltage source, wherein the applied voltage is smaller in magnitude than the breakdown voltage of the wafer solar cell 1 and, during the application of the voltage, the point light sources 4 are guided over the front or the back such that they are illuminated locally and a current flow is induced in the partial sections and acts on the partial sections. In a next step, the sandwich is transported to the unloading zone Z3, in which the contacting apparatuses 6 are spatially separated from the wafer solar cell 1. The two contacting apparatuses 6 are then moved in the return transport loop ZA back to the loading/contact zone Z1 in order to be reloaded.

The contacting apparatuses 6 are moved, together with contacted wafer solar cells 1, in one inline transport cycle, from the loading/contact zone Z1, through the illumination zone Z2 to the unloading zone Z3 and through the return transport loop ZA back to the loading/contact zone Z1 again, so as to provide a cyclic system suitable for inline mass production.

### LIST OF REFERENCE SIGNS

T Transport direction
1 Wafer solar cell
11 Front
12 Back
14 Front contact
15 Back contact
3 Wire
4 Point light source
5 Light beam
6 Contacting apparatus
61 Electrically conductive region
62 Transparent region
7 Voltage source

1. A device for improving the ohmic contact between a front contact and a doped layer of a wafer solar cell, the wafer solar cell having a front, a back, the front contact, the doped layer and a back contact, wherein the front contact and the back contact are strip-shaped or grid-shaped, the device comprising:
two contacting apparatuses, one for making electrical contact with the front contact and the other for making electrical contact with the back contact;
a voltage source having a pole for electrical connection to one of the contacting apparatuses and a further pole for electrical connection to the other of the contacting apparatuses; and
two point light sources, one point light source configured and designed to illuminate the front of the wafer solar cell and the other point light source configured and designed to illuminate the back of the wafer solar cell;
wherein the contacting apparatuses each have:
an optically transparent material that is coated with an optically transparent, electrically conductive layer, or
an optically transparent material having a multiplicity of electrically conductive wires that are integrated into a surface of the optically transparent material, or
an optically transparent, electrically conductive material having a multiplicity of microscopically thin, electrically conductive wires that are integrated into a surface of the optically transparent, electrically conductive material, or
a braid or a network consisting of a multiplicity of electrically conductive wires.

2. The device according to claim 1, wherein the optically transparent material coated with an optically transparent, electrically conductive layer is formed as a transparent material in the form of glass or plastic coated with optically transparent conductive oxides.

3. The device according to claim 1, wherein the multiplicity of electrically conductive wires are aligned parallel to one another, embedded in the surface of the transparent material in the form of a grid or braid.

4. The device according to claim 1, wherein the multiplicity of electrically conductive wires are formed from metal and/or a metal alloy.

5. The device according to claim 4, wherein the multiplicity of electrically conductive wires are formed from semi-precious and/or precious metals.

6. The device according to claim 1, wherein the front contact and the back contact have contact fingers arranged parallel to one another, having a contact finger width oriented parallel to the surface of the wafer solar cell and perpendicular to a direction of extent of the contact fingers, and in that the wires of the multiplicity of wires each have a width smaller than the contact finger width.

7. A method for improving ohmic contact behavior between a front contact and a doped layer of a wafer solar cell using the device according to claim 1, having the following steps:
a) electrically contact-connecting the front contact to one of the contacting apparatuses and the back contact to the other of the contacting apparatuses,
b) applying a voltage directed counter to the forward direction of the wafer solar cell to the front contact and the back contact by way of the voltage source, wherein the applied voltage is smaller in magnitude than a breakdown voltage of the wafer solar cell,
c) guiding one of the point light sources over a front partial section of the sun-facing front during the application of the voltage and guiding the other of the point light sources over a back partial section of the back facing away from the sun, wherein the distance between the front partial section and the back partial section is less than 5 mm, such that a current flow is induced in these partial sections and acts on these partial sections.

8. The method according to claim 7, wherein for step c), the distance between the front partial section and the back partial section is less than 3 mm,

9. The method according to claim 7, wherein steps a) to c) are carried out statically.

10. The method according to claim 7, wherein the device is designed as a component of an inline production facility for wafer solar cells and step a) comprises loading the contacting apparatuses with the wafer solar cell, and in that the wafer solar cell is transported, between steps a) and c), using the contacting apparatuses as a transport unit for the wafer solar cell, from a loading/contact zone of the device, in which steps a) and b) are performed, to an illumination zone, in which step c) is performed, and then transported to an unloading zone in which the contacting apparatuses are spatially separated from the wafer solar cell.

11. The method according to claim 10, wherein the contacting apparatuses of the device, which is designed as a component of an inline production facility, are moved, together with contacted wafer solar cells, in one inline transport cycle, from the loading/contact zone, through the illumination zone to the unloading zone and back to the loading/contact zone again in a return transport loop.
